(19) United States
(12) Patent Application Publication
(10) Pub. No.: US 2005/0093055 A1
(43) Pub. Date: May 5, 2005

(54) FLASH MEMORY AND METHOD THEREOF

(76) Inventors: Leo Wang, Hsin-Chu Hsien (TW); Chien-Chih Du, Hsin-Chu City (TW); Da Sung, Hsin-Chu City (TW); Chih-Wei Hung, Hsin-Chu City (TW); Vincent Huang, Hsin-Chu City (TW)

Correspondence Address: NORTH AMERICA INTERNATIONAL PATENT OFFICE (NAIPC), P.O. BOX 506, MERRIFIELD, VA, 22116, US

(21) Appl. No.: 10/709,505

(22) Filed: May 11, 2004

(30) Foreign Application Priority Data
Nov. 5, 2003 (TW) 092130992

(51) Int. Cl. G11C 11/34

(52) U.S. Cl. 257/314

(57) ABSTRACT

A substrate having a P type shallow doped region is provided, and at least a stacked gate structure having a tunneling oxide, a floating gate, an ONO layer, and a control gate from bottom to top are respectively formed thereon. Then, a P type deep doped region is formed in the substrate alongside the stacked gate structure. Following that, an oxidization process is performed to oxidize the floating gate and the control gate such that an insulating barrier layer is formed. Finally, a drain and a source are formed in the substrate.

### BACKGROUND OF INVENTION

1. Field of the Invention

The present invention relates to a flash memory and method thereof. More particularly, to a flash memory and method thereof capable of avoiding the gate disturb phenomenon.

2. Description of the Prior Art

As demands of portable electronic products increases, flash memories become more and more popular. The flash memory is normally applied to memory devices of digital cameras, cellular phones, and personal digital assistants. The flash memory is a kind of non-volatile memory having an advantage over volatile memory of being able to store data while power supply is interrupted.

Please refer to FIG. 1. FIG. 1 is a schematic diagram of a conventional flash memory cell 10. As shown in FIG. 1, the flash memory cell 10 is positioned on a substrate 12 and isolated from neighboring flash memory cells with field oxide layers 14. The flash memory cell 10 includes a drain 16, a source 18, and a stacked gate structure 20. The drain 16 and the source 18 are two non-adjacent doped regions positioned in the substrate 12 above a P well 15. The stacked gate structure 20 is formed on the surface of the substrate 12 between the drain 16 and the source 18. The stacked gate structure 20 includes from bottom to top a tunneling oxide 22, a floating gate 24, an ONO layer 26, and a control gate 28.

The flash memory cell 10 has a gate voltage V_{G} applied to the control gate 28 while the floating gate 24 is floating. When a programming step is executed, a low gate voltage V_{G} (such as −10V) is applied to the control gate 28, a drain voltage V_{D} (such as 6V) is applied to the drain 16, a base voltage V_{B} (such as 0V) is applied to the substrate 12, and the source remains floating. In such case, the electrons (e⁻) originally existing in the floating gate 24 will eject out and inject into the drain 18 under Fowler-Nordheim effect, so that the flash memory cell 10 is programmed. However, the drain voltage VD causes a depletion region 29 around the drain 16. This generates hot holes (e⁺), and further leads to a hot-hole injection phenomenon due to lateral electric field. The hot-hole injection phenomenon seriously affects normal operation of the flash memory cell 10.

In view of the disadvantages of the flash memory cell 10, another conventional flash memory cell has been proposed. Please refer to FIG. 2. FIG. 2 is a schematic diagram of another conventional flash memory cell 30. For convenience, same reference numbers stand for same components in FIG. 1 and FIG. 2. As shown in FIG. 2, differing from the flash memory cell 10, the drain 16 and the P well 15 of the flash memory cell 30 are electrically connected together and are applied with an identical voltage, such as 6V. In that case, the flash memory cell 30 operates under channel Fowler-Nordheim effect. Thus the depletion region 29 will not be generated in the junction between the drain 16 and the P well 15, and neither will be the hot holes.

Although employing the channel Fowler-Nordheim effect in the foregoing flash memory cell 30 can overcome drawbacks, this may result in other problems as well. Although the drain 16 and the P well 15 are electrically connected together, the P well 15, however, extends into the substrate 12, and the neighboring flash memory cells could be influenced.

To avoid the neighboring flash memory cells being affected due to the electrical connection of the drain 16 and the P well 15, another flash memory cell 40 is proposed. Please refer to FIG. 3. FIG. 3 is a schematic diagram of another conventional flash memory cell 40. As shown in FIG. 3, the flash memory cell 40 is formed on a substrate 42, and isolated by field oxide layers 44. The flash memory cell 40 includes an N type drain doped region 46, an N type source doped region 48, a stacked gate structure 50 positioned in the substrate 42 between the drain doped region 46 and the source doped region 48, a P type shallow doped region 51 positioned in the substrate 42 under the stacked gate structure 50, and a P type deep doped region 52 positioned in the substrate 42 under the drain doped region 46. The stacked gate structure 50 further includes a tunneling oxide 53, a floating gate 54, an ONO layer 55, and a control gate 56. In addition, the deep doped region 52 functions as a P well, and each flash memory cell corresponds to a P well. Thus, the operation of neighboring flash memory cells will not be influenced even if the drain doped region 46 and the deep doped region 52, which serves as a P well, are electrically connected together.

Though the conventional flash memory cell 40 overcomes the disadvantage of the flash memory cell 30, other problems appears, however. For example, when the flash memory cell 40 is applied to a BiNOR (Bi-directional tunneling NOR) flash memory, a gate disturb phenomenon will occur. Please refer to FIG. 4 and FIG. 5. FIG. 4 is a circuit chart of conventional flash memory cells shown in FIG. 3. FIG. 5 is a schematic diagram illustrating a neighboring flash memory cell shown in FIG. 4 in a programming step. For convenience, same reference numbers stand for same components in FIG. 3 and FIG. 5. As shown in FIG. 4 and FIG. 5, the flash memory cell 40 and a neighboring flash memory cell 401 share a control gate. As a result, the flash memory cell 401 is applied with a gate voltage V_{G1}=−10V, while the drain voltage V_{D1}, the source V_{S}, and the base voltage V_{B} are 0V, 6V, and 0V. In such case, the potential difference between the gate 56 (not shown in FIG. 4) and the source 48 (not shown in FIG. 4) reaches 16V. This high potential difference forces the electrons originally existing in the floating gate 54 to eject out and inject into the source 48, and further result in a current leakage problem, known as gate disturb phenomenon. As to the neighboring flash memory cells that share the bit line with the flash memory cell 40 in the programming step, a gate voltage V_{G2}=−2V is normally applied for avoiding a charging pumping problem.

It is therefore an important topic to find out a solution for avoiding the gate disturb phenomenon among neighboring flash memory cells of a BiNOR flash memory.

### SUMMARY OF INVENTION

It is therefore a primary objective of the present invention to provide a flash memory and method thereof for avoiding the gate disturb problem of the conventional flash memory.

According to the claimed invention, a flash memory and method thereof is disclosed. First, a substrate having a first conductive type shallow doped region is provided, the substrate including thereon at least a stacked gate structure which has a tunneling oxide, a floating gate, an insulating layer, and a control gate. Then, a first conductive type deep doped region is formed in the substrate alongside the substrate. Flowing that, the edge part of the floating gate and the control gate is oxidized to form a rounded insulating barrier layer, and the dopants of the deep doped region are driven in simultaneously. Finally, two second conductive type doped regions, respectively functioning as a drain and a source, are formed in the substrate alongside the stacked gate structure.

It is an advantage of the present invention that an insulating barrier layer having a rounded shape is formed at the edge part of the floating gate. As a result, the gate disturb problem of a BiNOR flash memory is prevented.

These and other objects of the present invention will be apparent to those of ordinary skill in the art after having read the following detailed description of the preferred embodiment that is illustrated in the various figures and drawings.

### BRIEF DESCRIPTION OF DRAWINGS

FIG. 1 is a schematic diagram of a conventional flash memory cell.

FIG. 2 is a schematic diagram of another conventional flash memory cell.

FIG. 3 is a schematic diagram of another conventional flash memory cell.

FIG. 4 is a circuit chart of conventional flash memory cells shown in FIG. 3.

FIG. 5 is a schematic diagram illustrating a neighboring flash memory cell shown in FIG. 4 in a programming step.

FIG. 6 to FIG. 13 are schematic diagrams illustrating a method of forming a flash memory cell according to the present invention.

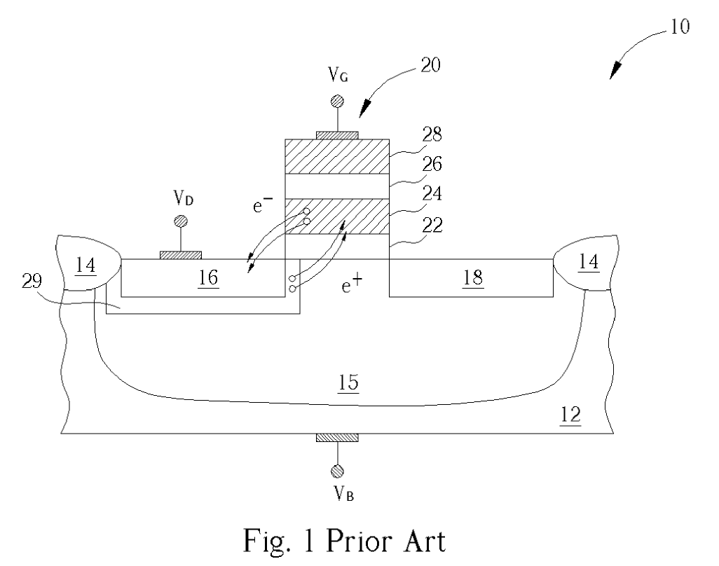

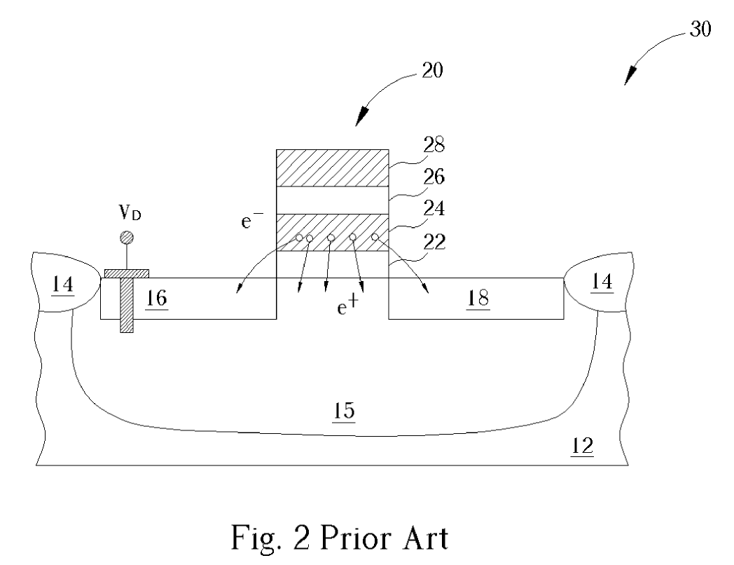

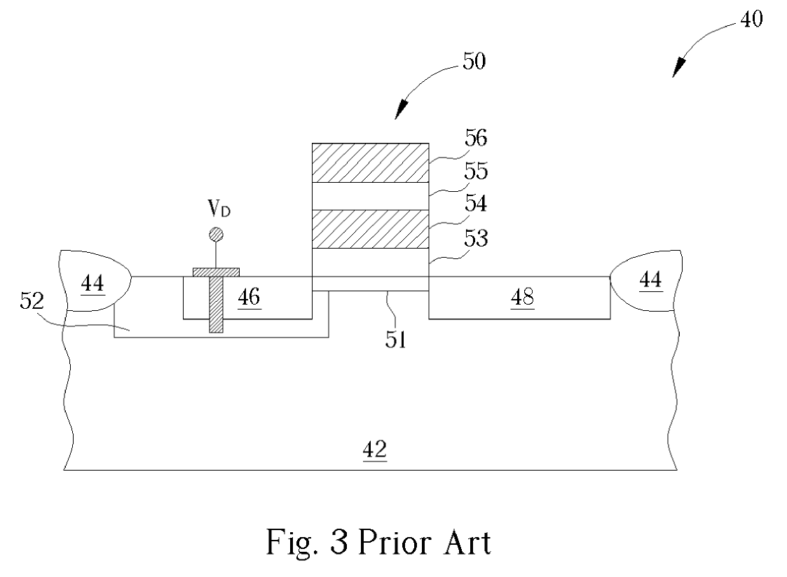

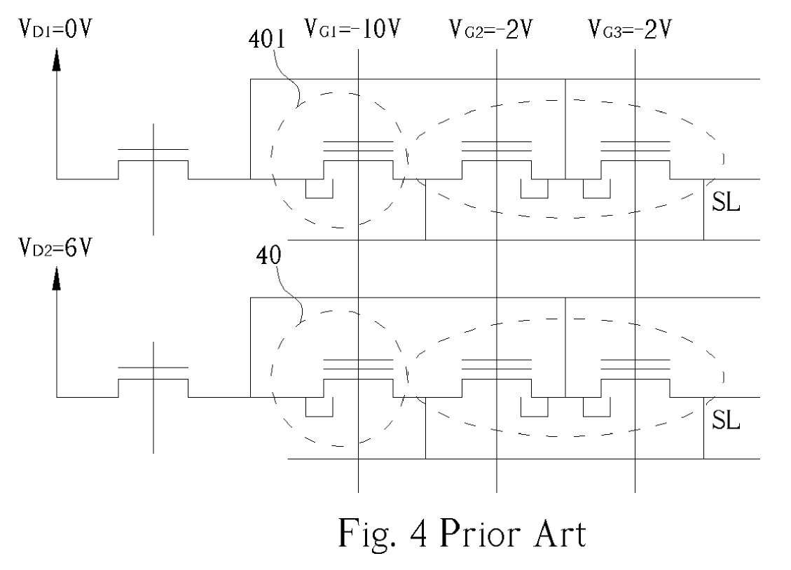

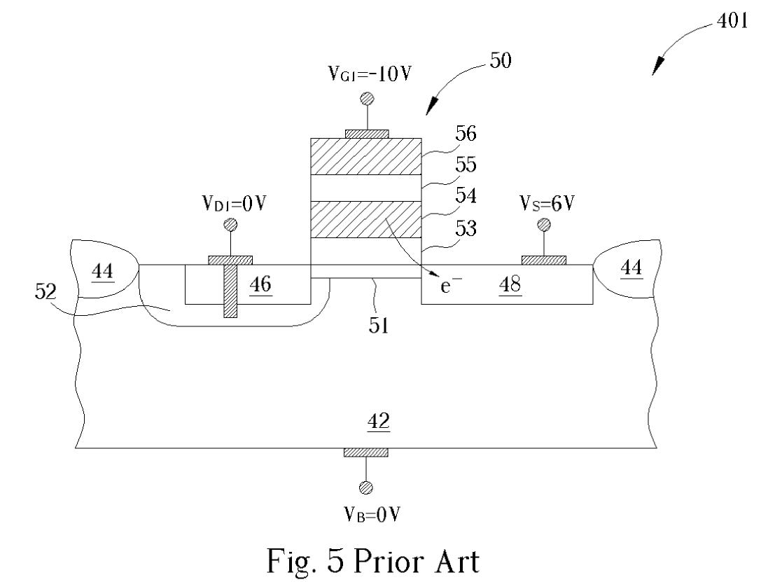

### DETAILED DESCRIPTION

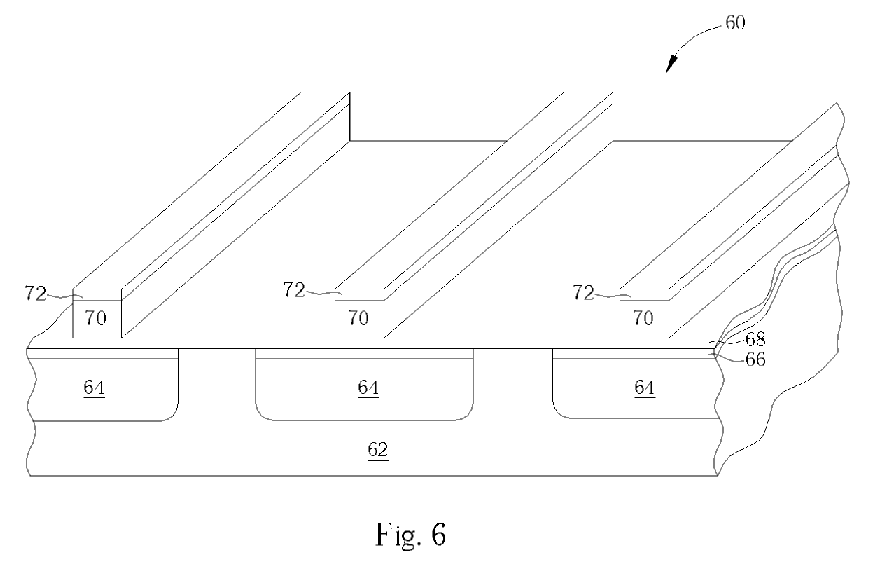

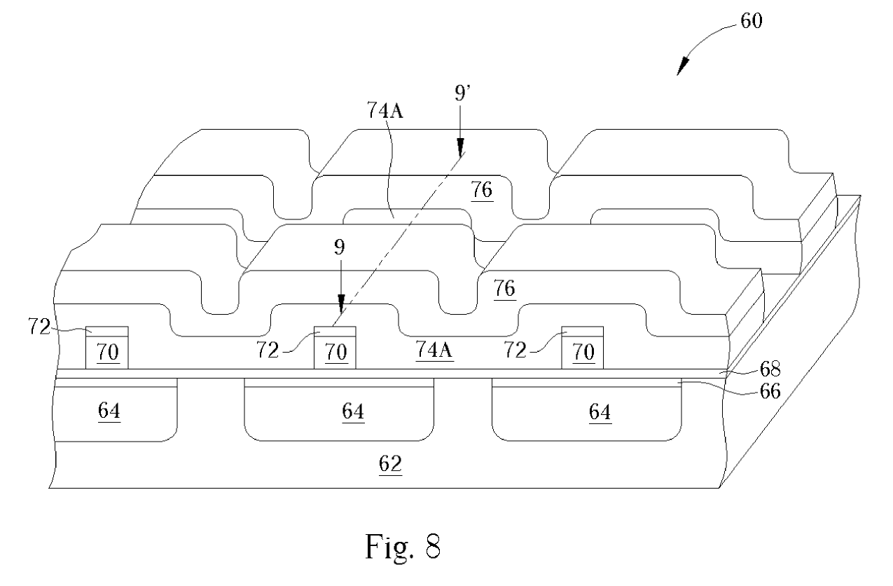

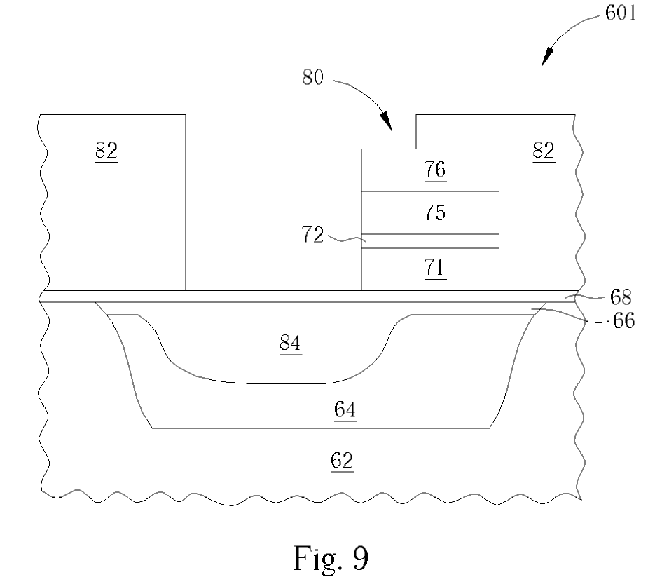

Please refer to FIG. 6 to FIG. 13. FIG. 6 to FIG. 13 are schematic diagrams illustrating a method of forming a flash memory 60 according to the present invention. It is worth noting that FIG. 6 to FIG. 8 are perspective views of the flash memory 60, while FIG. 9 to FIG. 13 are cross-sectional diagrams showing a single flash memory cell 601 along line 99 shown in FIG. 8. As shown in FIG. 6, a substrate 62 is provided. The substrate 62 includes a plurality of N type wells 64 arranged in arrays, and a plurality of P type shallow doped regions 66 above and corresponding to the wells 64 in the substrate 62. Each well 64 is surrounded by shallow trench insulating (STI) layers (not shown) or field oxide layers (not shown). Then, an oxide layer 68, a first polysilicon layer (not shown), and an ONO (oxide-nitride-oxide) layer 72 are formed respectively on the substrate 62. Following that, a photoresist pattern (not shown) is employed as a hard mask to remove a portion of the ONO layer 72 and the first polysilicon layer (not shown) for forming a plurality of first polysilicon patterns 70 arranged in parallel and crossing the wells 64. Finally, the photoresist pattern (not shown) is removed. It is worth noting that the N type wells 64 are formed by doping VA group elements, such as phosphorous or arsenic, in an ion implantation process, while the P type shallow doped regions 66 are formed by doping IIIA group elements, such as boron, with lower doping energy in another ion implantation process.

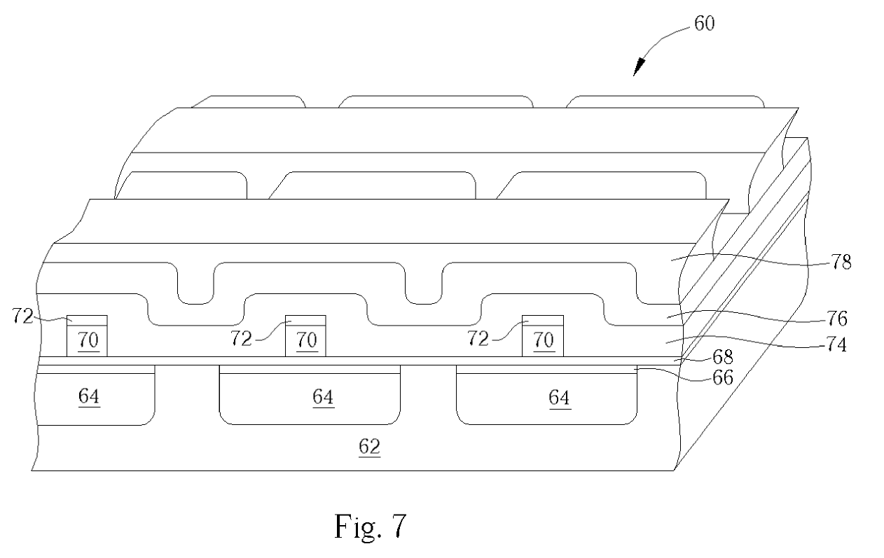

As shown in FIG. 7, a second polysilicon layer 74 and at least a gap layer 76 are respectively deposited on the ONO layer 72 and the oxide layer 68. Then, another photoresist pattern 78 is formed on the gap layer 76 for defining word lines (not shown) and the position of control gate (not shown). The materials used to form the gap layer 76 are selected from TEOS, silicon nitride, or any other suitable materials.

As shown in FIG. 8, the gap layer 76 and the second polysilicon layer 74, which are not protected by the photoresist pattern (not shown), are removed to form a plurality of second polysilicon patterns 74A (i.e. word lines) parallel with the first polysilicon patterns 70. Following that, the ONO layer 72 and the first polysilicon patterns 70, which are not protected by the photoresist pattern (not shown), are removed. Finally, the photoresist pattern (not shown) is removed to form a plurality of stacked gate structure (not shown) arranged in arrays. It is worth noting that the first polysilicon patterns 70 serve as floating gates (not shown) while the second polysilicon patterns 74A serve as control gates (not shown).

In addition, for improving the conductivity of the control gate (not shown), a silicide layer, such as tungsten silicide, (not shown) can be selectively formed on the second polysilicon layer 74. The silicide layer (not shown) can be formed on the second polysilicon layer 74 before the gap layer 76 is deposited, and removed as well as the gap layer 76 and the second polysilicon layer 74 by using the photoresist pattern (not shown) as a hard mask.

As shown in FIG. 9, another photoresist pattern 82 is formed on the substrate 62 and the stacked gate structure 80. The photoresist pattern 82 is employed as a hard mask to perform an ion implantation process for forming a P type deep doped region 84 in the substrate 62 at one side of the stacked gate structure 80. In this embodiment, boron ions having concentration of 4*10⁻¹³ atoms/cm³ are selected as dopants, and the doping energy is about 30 kev. Additionally, since the deep doped region 84 is formed in the substrate 62 at one side of the stacked gate structure 80, the deep doped region 84 is self-aligned.

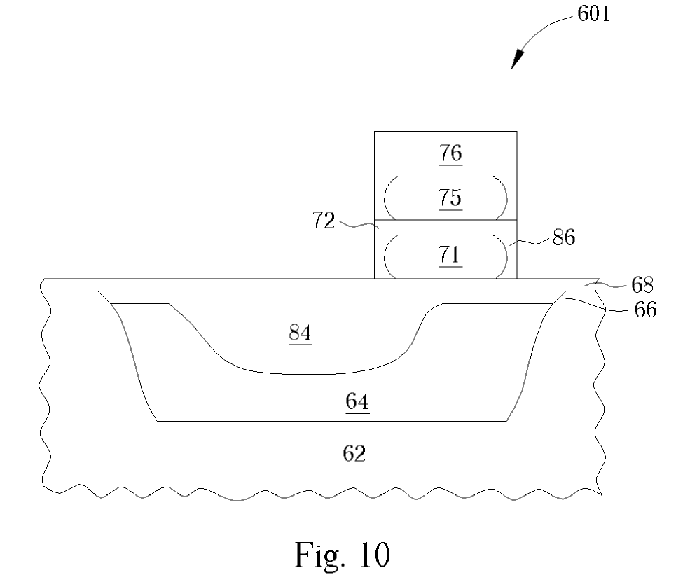

As shown in FIG. 10, an oxidization process is performed after the photoresist pattern 82 is removed. The oxidization process is for oxidizing the edge part of the floating gate 71 and the control gate 75, so that a rounded insulating barrier layer 86 is formed at the edge of the floating gate 71. Simultaneously, the dopants of the deep doped region 84 are driven in. In this embodiment, the reaction time of the oxidization process is about 30 minutes, and the reaction temperature is between 800° C. to 1000° C. In addition, the insulating barrier layer 86 can also be a composite-layer structure. Consequently, at least a rapid thermal nitridation (RTN) process or another rapid thermal oxidization (RTO) process can be alternatively carried out to form at least a nitride layer or another oxide layer for enhancing the barrier effect.

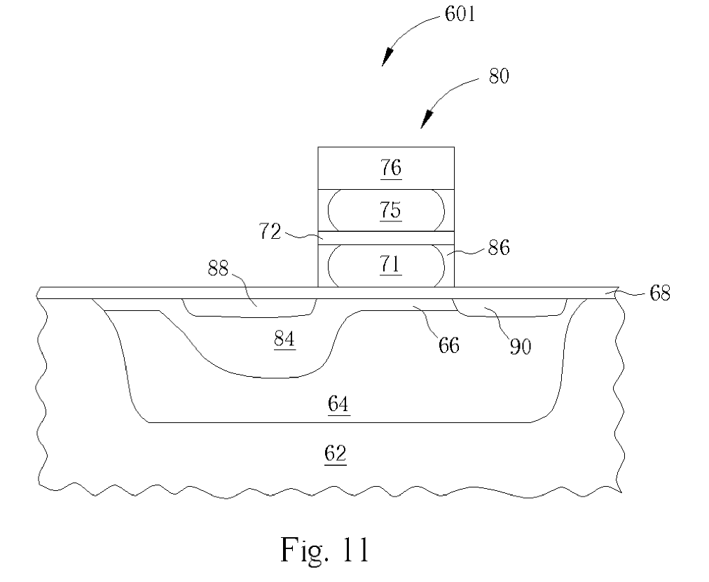

As shown in FIG. 11, another ion implantation process is performed for respectively forming an N type drain doped region 88 and a N type source doped region 90 in the substrate 62 alongside the stacked gate structure 80. It is worth noticing that the ion implantation process can be carried out directly or by using a photoresist pattern (not shown). In this embodiment, arsenic ions having concentration of 3*10⁻¹⁴ atoms/cm³ are selected as dopants, and the doping energy is about 30 kev.

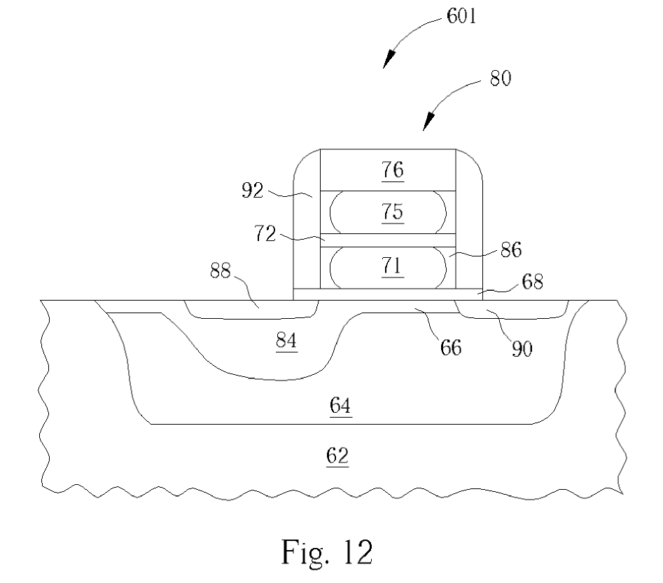

As shown in FIG. 12, a silicon nitride layer (not shown) is deposited on the oxide layer 68 and the stacked gate structure 80, and is etched back to remove a portion of the silicon nitride layer (not shown) for forming a spacer 92 on sidewalls of the stacked gate structure 80.

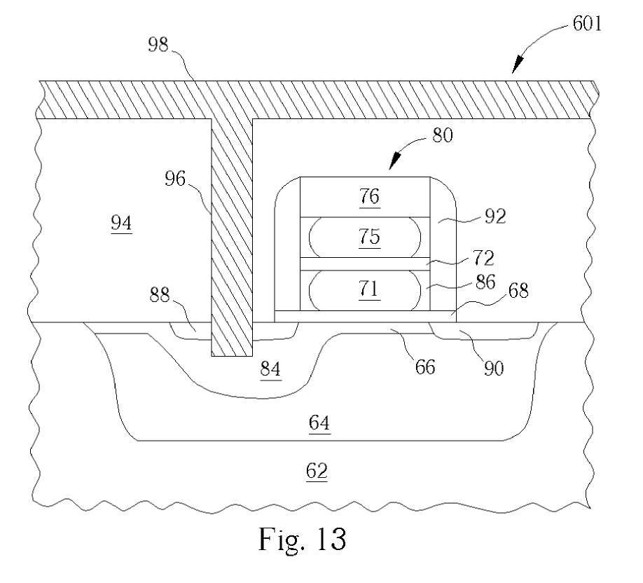

As shown in FIG. 13, an inter-layer dielectric 94 is deposited on the substrate 62, and is etched back to remove a portion of the inter-layer dielectric 94 positioned on the drain doped region 88 and a portion of the substrate 62 in the deep doped region 84, such that a contact hole (not shown) is formed. Then, a bit line contact 96 and a bit line 98 are formed. The bit line electrically connects to the drain doped region 88 and the deep doped region 84. It is worth noticing that the bit line contact 96 can be any suitable type of contact, such as tungsten contact, or directly formed with the bit line 96. Technologies of forming the bit line 98 and the bit line contact 96 are well known, thus details are not given here.

In comparison with the prior art, the floating gate and the control gate of the flash memory has an insulating barrier layer with a rounded shape. This rounded insulating barrier layer is capable of preventing current leakages. Consequently, when a flash memory cell executes a programming step, neighboring flash memory cells will not be disturbed.

Those skilled in the art will readily appreciate that numerous modifications and alterations of the device may be made without departing from the scope of the present invention. Accordingly, the above disclosure should be construed as limited only by the metes and bounds of the appended claims.

1. A method of forming a flash memory comprising:
providing a substrate having a first conductive type shallow doped region;
forming at least a stacked gate structure, the stacked gate structure from bottom to top comprising a tunneling oxide, a floating gate, an insulating layer, and a control gate;
performing a first ion implantation process to form a first conductive type deep doped region in the substrate alongside the stacked gate structure;
performing an oxidization process to oxidize an edge part of the floating gate and the control gate for forming an insulating barrier layer having a rounded shape, and for driving in dopants of the deep doped region;
performing a second ion implantation process to form two second conductive type doped regions, which respectively serve as a drain and a source of the flash memory, in the substrate alongside the stacked gate structure; and
forming a bit line contact and a bit line, the bit line being electrically connected to the drain and the deep doped region through the bit line contact.

2. The method of claim 1 wherein the substrate further comprises a second conductive type well, and the shallow doped region, the deep doped region, the drain, and the source are positioned above the second conductive type well.

3. The method of claim 2 wherein the first conductive type is P type and the second conductive type is N type.

4. The method of claim 1 wherein the control gate further comprises a silicide layer thereon.

5. The method of claim 1 wherein the stacked gate structure further comprises a TEOS layer thereon.

6. The method of claim 1 wherein the insulating barrier layer is an oxide layer, and the oxidization process is performed at a temperature ranging from 800° C. to 1000° C.

7. The method of claim 1 wherein the insulating barrier layer is a composite-layer structure comprising at least an oxide layer and at least a nitride layer.

8. The method of claim 7 wherein the nitride layer is formed by a rapid thermal nitridation (RTN) process.

9. The method of claim 1 wherein the insulating layer is an ONO (oxide-nitride-oxide) layer.

10. The method of claim 1 wherein after the drain and the source are formed, the method further comprises:
forming a spacer alongside the stacked gate structure; and
forming an inter-layer dielectric, which covers the stacked gate structure and the spacer, on the substrate.

11. The method of claim 1 wherein the flash memory is a BiNOR flash memory.

12. A flash memory cell comprising:
a substrate;
a stacked gate structure positioned on the substrate, wherein the stacked gate structure from bottom to top comprises a tunneling oxide, a floating gate, an insulating layer, and a control gate, the floating gate and the control gate having an insulating barrier layer with rounded edges;
a first conductive type shallow doped region positioned in the substrate under the stacked gate structure;
a first conductive type deep region positioned in the substrate at one side of the stacked gate structure;
a second conductive type drain doped region positioned in the substrate at a same side with the deep doped region, a bottom and sidewalls of the drain doped region being surrounded by the deep doped region; and
a second conductive type source doped region positioned in the substrate at an opposite side of the stacked gate structure.

13. The flash memory cell of claim 12 wherein the substrate further comprises a second conductive type well, and the shallow doped region, the deep doped region, the drain doped region, and the source doped region are positioned above the second conductive type well.

14. The flash memory cell of claim 12 wherein the first conductive type is P type and the second conductive type is N type.

15. The flash memory cell of claim 12 wherein the control gate further comprises a silicide layer thereon.

16. The flash memory cell of claim 12 wherein the stacked gate structure further comprises a TEOS layer thereon.

17. The flash memory cell of claim 12 wherein the insulating layer is an oxide layer.

18. The flash memory cell of claim 12 wherein the insulating barrier layer composite-layer structure comprises at least an oxide layer and at least a nitride layer.

19. The flash memory cell of claim 12 wherein the insulating layer is an ONO (oxide-nitride-oxide) layer.

20. The flash memory cell of claim 12 wherein the drain doped region and the deep doped region are electrically connected together.
